(19) United States
(12) Patent Application Publication
(10) Pub. No.: US 2013/0140620 A1
(43) Pub. Date: Jun. 6, 2013

(54) Flash Memory and Manufacturing Method Thereof

(71) Applicants: Tzung-Han Lee, Taipei City (TW); Chung-Lin Huang, Taoyuan County (TW); Ron Fu Chu, Taipei City (TW); Dah-Wei Liu, Taipei City (TW)

(72) Inventors: Tzung-Han Lee, Taipei City (TW); Chung-Lin Huang, Taoyuan County (TW); Ron Fu Chu, Taipei City (TW); Dah-Wei Liu, Taipei City (TW)

(21) Appl. No.: 13/398,853

(22) Filed: Feb. 17, 2012

(30) Foreign Application Priority Data
Dec. 1, 2011 (TW) 100144200

(51) Int. Cl. H01L 29/78; H01L 21/28

(52) U.S. Cl. 257/314; 438/684; 257/E21.158; 257/E29.255

(57) ABSTRACT

The present invention discloses a flash memory. The flash memory includes a substrate and a memory string, a plurality of landing pads, a plurality of common source lines, a plurality of bit line contacts and at least a bit line, which are disposed on the substrate in sequence. The memory string includes a plurality of storage transistors. The landing pads are disposed between each of the storage transistors. The common source lines and the bit line contact are electrically connected to the landing pads alternatively. The common line is disposed on the common line contacts and is electrically connected thereto. The present invention further provides a manufacturing method of making the same.

### BACKGROUND OF THE INVENTION

1. Field of the Invention

The present invention relates to a flash memory, and more particularly, to a NAND flash memory having a landing pad between each storage transistor so as to enhance the programming speed.

2. Description of the Prior Art

Recently, as demand for portable electronic devices is increasing, the market for flash memories and electrically erasable programmable read-only memories (EEPROM) is expanding. The aforesaid portable electronic devices include storage memories for digital cameras, cellular phones, video game apparatuses, portable digital assistances (PDA), telephone answering machines, programmable ICs, and the likes.

A flash memory is a non-volatile memory, and has the main characteristic of being able to store data in the memory even though the power is turned off. By changing the threshold voltage of the transistor, the gate can be turned on or off, and the data can be stored in transistors. Generally speaking, the flash memories can be divided into two types of configurations, namely, the NOR flash memories and the NAND flash memories. The NOR flash memory has a higher programming speed and is suitable for code flash memories and is mainly used to execute program coding. The NAND flash memory has a denser configuration and is suitable for data flash memories and is mainly used for data storage. However, the operation speed of the NAND flash memory is relatively slower than that of the NOR flash memory.

### SUMMARY OF THE INVENTION

The present invention therefore provides a flash memory and a manufacturing method thereof. In particular, the present invention provides a NAND flash memory and a manufacturing method thereof, which can effectively enhance the operation speed.

According to one embodiment of the present invention, a flash memory is provided. The flash memory includes a substrate and a memory string, a plurality of landing pads, a plurality of common source lines, a plurality of bit line contacts and at least a bit line, which are disposed on the substrate. The memory string includes a plurality of storage transistors. The landing pads are disposed between every storage transistor. The common source lines and the bit line contact are electrically connected to the landing pads alternatively. The common line is disposed on the common line contacts and is electrically connected thereto.

According to another embodiment of the present invention, a method of manufacturing a flash memory is provided. First, a substrate is provided and an active region is formed therein. A memory string having a plurality of storage transistors is formed within the active region. Then, a first dielectric layer is formed on the memory string. A plurality of landing pads are formed above the first dielectric layer and located between each two storage transistors. A plurality of common source lines are formed on the first dielectric layer and then a second dielectric layer is formed on the first dielectric layer. Lastly, a plurality of bit line contacts are formed in the second dielectric layer and a plurality of bit lines are formed above the second dielectric layer.

Compared to conventional NAND flash memory and its manufacturing method, the flash memory set forth in the present invention includes common source lines, landing pads and bit line contacts. Consequently, each storage transistor can be operated individually and the operation speed can therefore be enhanced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 show schematic diagrams of the flash memory according to the present invention.

FIG. 3 to FIG. 8 show schematic diagrams of the method of manufacturing the flash memory according to the present invention.

### DETAILED DESCRIPTION

In order to provide a better understanding of the present invention to those of ordinarily skilled in the art, several preferred embodiments are enumerated with reference to the accompanying drawings, to explain the construction and the desired efficacy of the present invention.

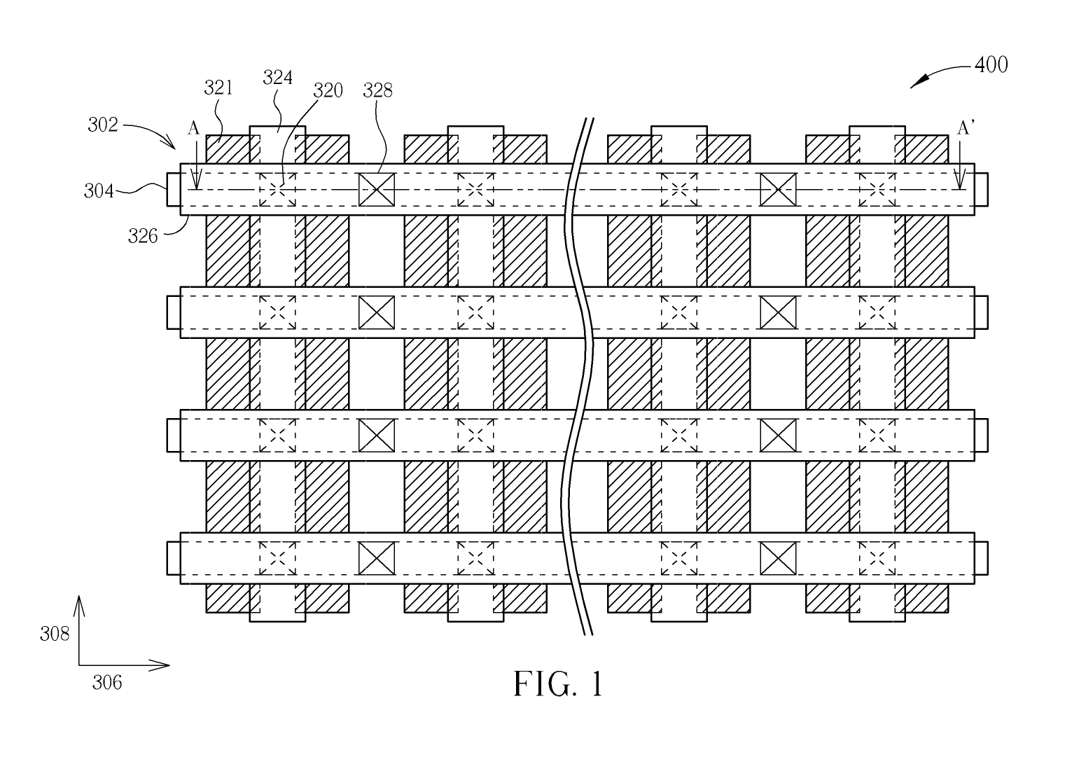

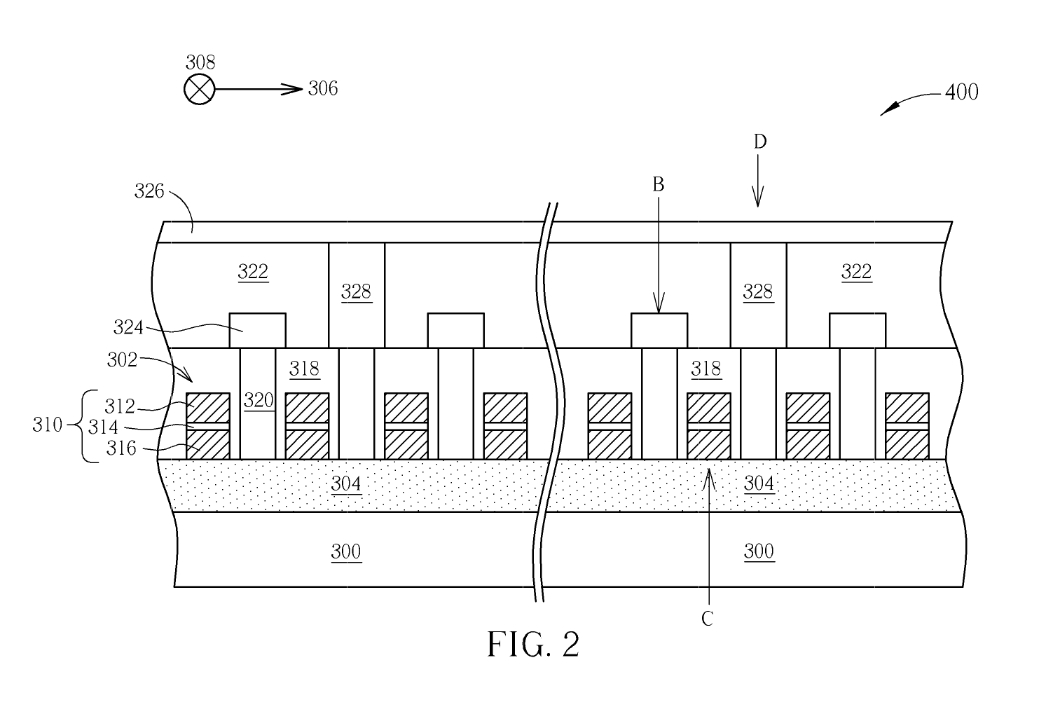

Please refer to FIG. 1 and FIG. 2, which show schematic diagrams of the flash memory set forth in the present invention. FIG. 2 shows a cross-sectional view along the AA′ line drawn in FIG. 1. As shown in FIG. 1, the flash memory 400 in the present invention includes a substrate 300 and at least a memory string 302. The substrate 300 can be a silicon substrate, an epitaxial silicon substrate, a silicon germanium substrate, a silicon carbide substrate or a silicon-on-insulator (SOI) substrate, but is not limited thereto.

As shown in FIG. 1, the flash memory 400 in the present invention includes at least an active region 304 disposed in the substrate 300, each of which is extending along a first direction 306 and substantially parallel to each other. Preferably, these active regions 304 are separated by a plurality of isolation regions (not shown). In addition, the flash memory 400 further includes a plurality of word lines 322, a plurality of common source lines 324 and a plurality of bit lines 326, which are disposed on the substrate 300. In one preferred embodiment, the word lines 321 are parallel to each other and extending along a second direction 308. The common source lines 324 are parallel to each other and extending along the second direction 308. The bit lines 326 are parallel to each other, extending along the first direction 306 and substantially overlapping the active regions 304. In one preferred embodiment, the first direction 306 is perpendicular to the second direction 308.

As shown in FIG. 2, the active region 304 is disposed in the substrate 300 and has appropriate dopants. A first dielectric layer 318 and a second dielectric layer 320, such as SiO₂ or other suitable materials, are sequentially disposed on the substrate 300. The memory string 302 is disposed in the first dielectric layer 318 and above the corresponding active region 304. The memory string 302 includes a plurality of storage transistors 310. In one preferred embodiment, the storage transistor 310 includes a control gate 312, a dielectric layer 314 and a floating gate 316. Each word line 321 electrically connects each corresponding control gate 312. In one embodiment, the storage transistor 310 further includes a cap layer (not shown), a spacer (not shown) or other structures according to the design of the devices. In another embodiment, the memory string 302 can further includes other types of transistors with different functions, such as selecting transistors.

The common source lines 324 are disposed above the first dielectric layer 318 and in the second dielectric layer 322. The bit lines 326 are disposed above the second dielectric layer 322. As shown in FIG. 1, since the active regions 304, the word lines 321, the common source lines 324 and the bit lines 326 are respectively extending along the first direction 306 or the second direction 308, as shown in FIG. 2, these connection lines are located in different dielectric layers correspondingly and are connected to the storage transistors 310 through the landing pads 320 in the first dielectric layer 318 or the bit line contacts 328 in the second dielectric layer 322. More specifically, the landing pads 320 are disposed in the first dielectric layer 318 and located between every storage transistor 310. The landing pads 320 contact downwardly the active region 304 and contact upwardly the common source line 324 or the bit line contact 328. The common source lines 324 and the bit line contacts 328 are disposed in the second dielectric layer 322. In one preferred embodiment, the common source lines 324 and the bit line contacts 328 are arranged alternatively to electrically connect the landing pads 320. This means that two common source lines 324 are not connected to two adjacent landing pads 320 in one memory string 302, and two bit line contacts 328 are not connected to two adjacent landing pads 320 in one memory string 302. As shown in FIG. 2, the bit line contact 328 penetrates the second dielectric layer 322 to electrically connect the landing pad 320 and the bit line 326. The bit lines 326 are disposed on the second dielectric layer 322 to electrically connect the bit line contacts 328 in one memory string 302.

In conventional arts, the storage transistors in one memory string of a NAND flash memory are operated by only one common source line and one bit line. Consequently, the operation speed is relatively slow. The flash memory 400 in the present invention however specifically includes the common source lines 324, the landing pads 320 and the bit line contacts 328, which are correspondingly connected to each of the storage transistors 310, so that each of the storage transistors 310 can be operated individually. As shown in FIG. 2 for example, the storage transistor C can be operated by controlling the word line of the storage transistor C, the common source line B and the bit line D. This way, the reading or programming speed of the flash memory 400 can be accelerated. In one preferred embodiment, the common source line 324, the landing pads 320 and the bit line contacts 328 can be made of appropriate low resistance materials, for example, poly-silicon or metal, such as Cu, Al, Au, Ag, Mo, Ti, Ta, Cd or nitride thereof, oxide thereof, alloy thereof, or the combinations thereof, so as to enhance the operation speed.

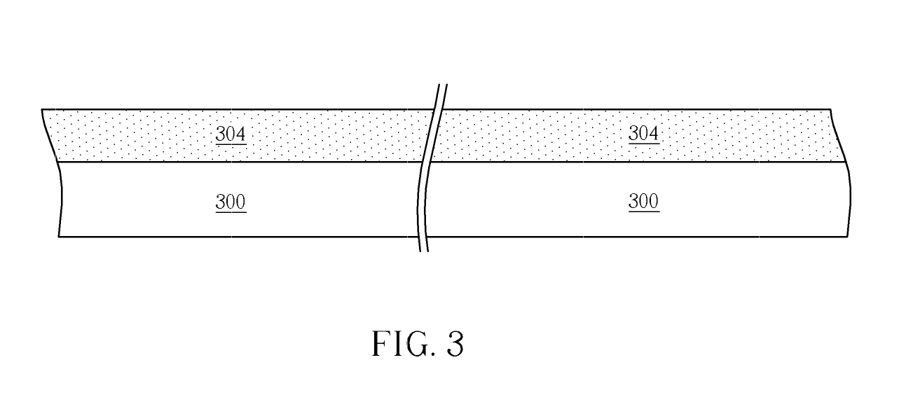

Please refer to FIG. 3 to FIG. 8, which show schematic diagrams of the method of manufacturing the flash memory of the present invention. FIG. 3 to FIG. 8 are cross-sectional views along the line AA′ in FIG. 1. As shown in FIG. 3, a substrate 300 is provided. The substrate 300 can be a silicon substrate, an epitaxial silicon substrate, a silicon germanium substrate, a silicon carbide substrate or a silicon-on-insulator substrate, but is not limited thereto. An active region 304 is formed in the substrate 300 by using an implant doping process for example. In one embodiment, the active region extends along a first direction 306.

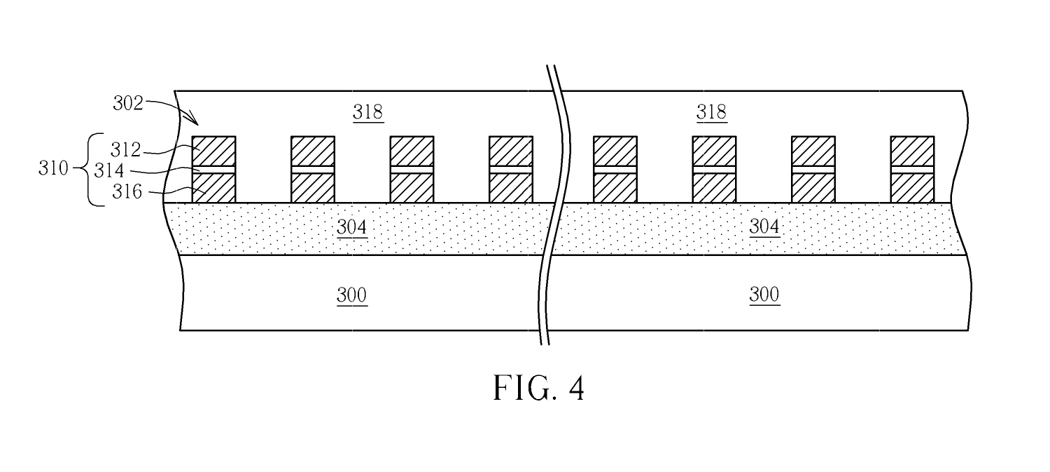

As shown in FIG. 4, a memory string 302 is formed within the active region 304. The memory string 302 may include a plurality of storage transistors 310. In one embodiment, the storage transistor 310 includes a control gate 312, a dielectric layer 314 and a floating gate 316. In one embodiment, the storage transistor 310 further includes a cap layer (not shown), a spacer (not shown) or other structures according to the design of the devices. In another embodiment, the memory string 302 can further include other types of transistors with different functions, such as selecting transistors. It is understood that the memory string 302 is formed simultaneously with the word line 321. Subsequently, a first dielectric layer 318 such as a SiO₂ layer is formed on the substrate 300 to cover the memory string 318.

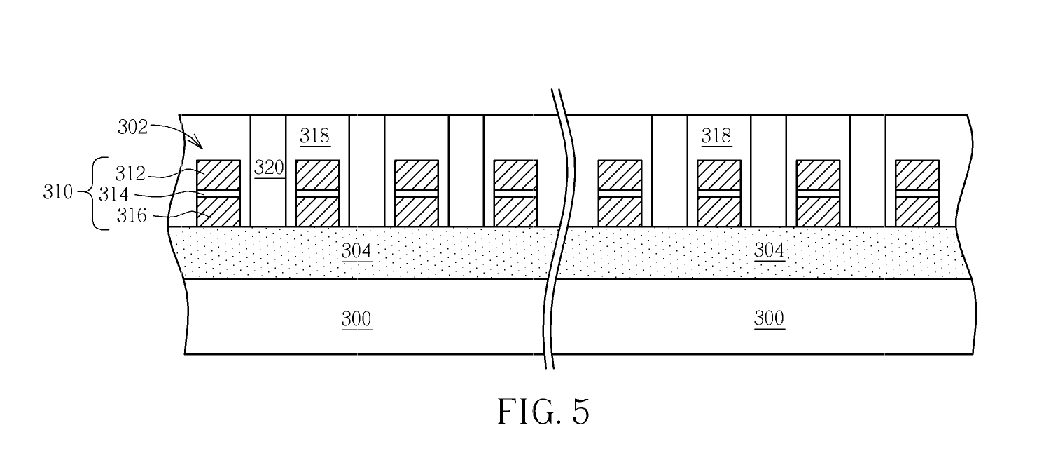

As shown in FIG. 5, a plurality of landing pads 320 are formed in the first dielectric layer 318 and located between each of the two storage transistors 310. In one preferred embodiment, the landing pads 320 can be formed by a conventional metal interconnection fabrication process such as a damascene process. The landing pad 320 may include a low resistance material such as poly-silicon or metal.

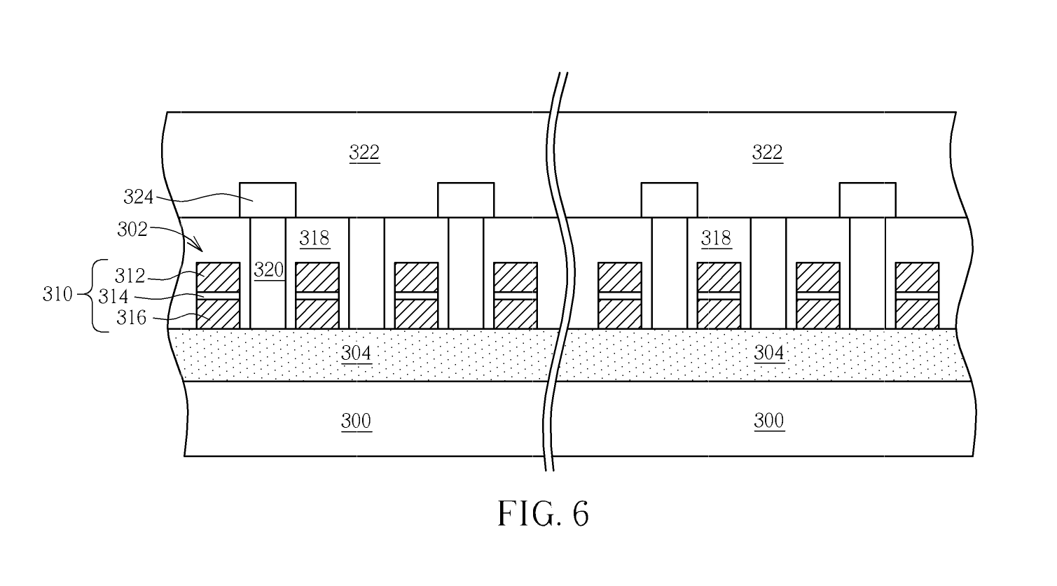

As shown in FIG. 6, at least a common source line 324 is formed on the first dielectric layer 318 in a manner that the landing pads 320 are alternatively connect to the common source lines 324. That is, two common source lines 324 are not connected to two adjacent landing pads 320 in one memory string 302. The common source lines 324 may include a low resistance material such as poly-silicon or metal. Then, a second dielectric layer 322 is formed on the first dielectric layer 318 to cover the common source lines 324. The second dielectric layer 322 includes SiO₂ for example.

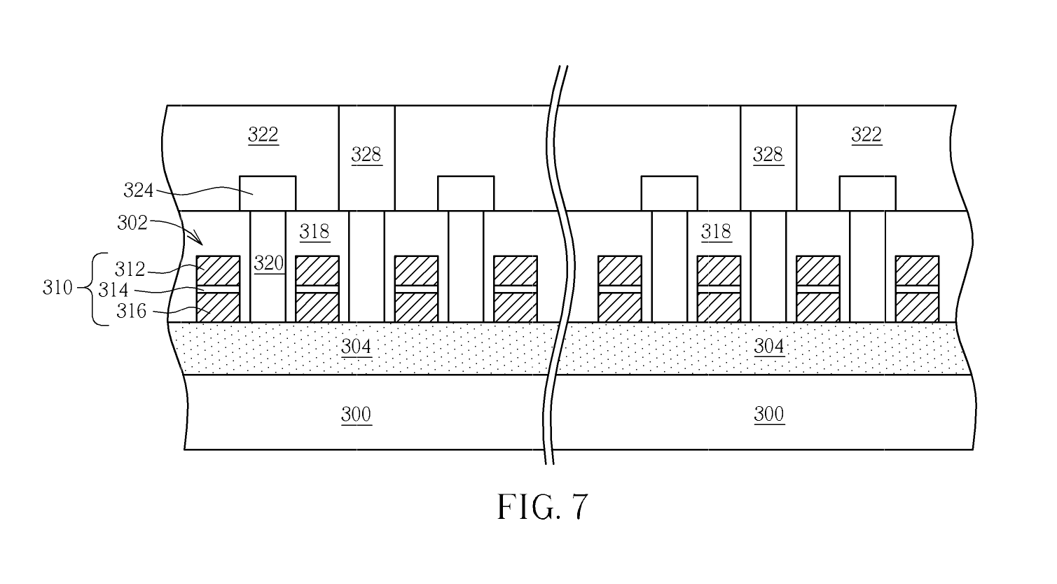

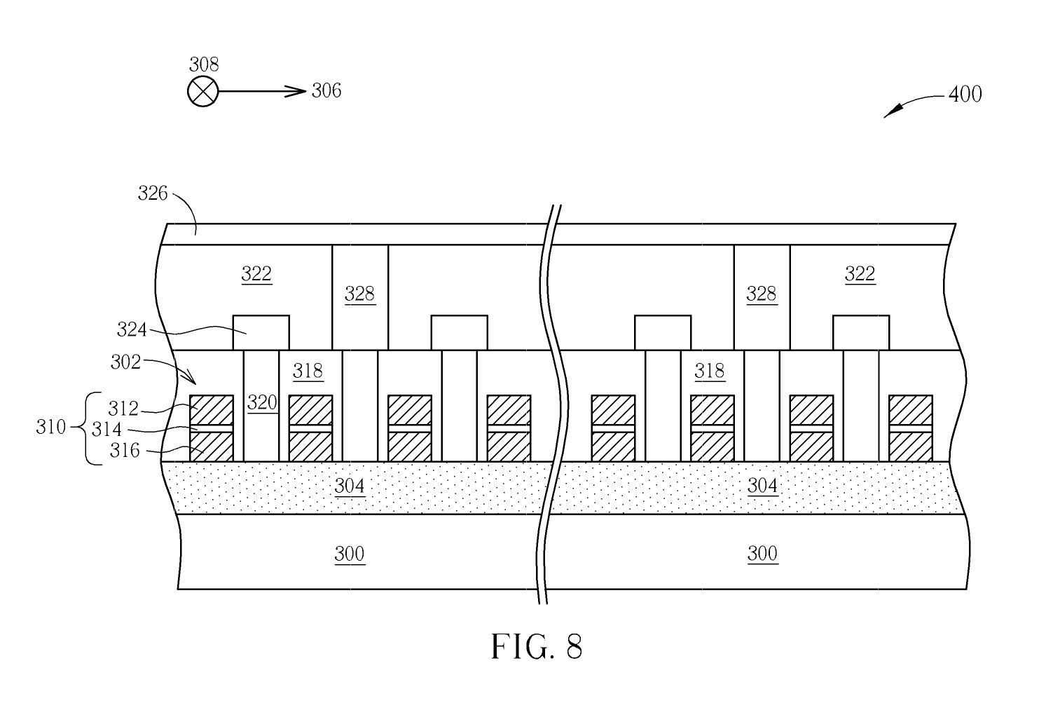

As shown in FIG. 7, a plurality of bit line contacts 328 are formed in the second dielectric layer 322. The bit line contacts 328 are electrically connected to the landing pads 320 that are not connected to the common source lines 324. That is, two bit line contacts 328 are not connected to two adjacent landing pads 320 in one memory string 302. In one preferred embodiment, the bit line contacts 328 can be formed by a conventional metal interconnection fabrication process such as a damascene process. Finally, as shown in FIG. 8, at least a bit line 326 is formed on the second dielectric layer 322 to electrically connect the bit line contact 328 corresponding to the same active region 304, thereby completing the flash memory 400 of the present invention.

To sum up, the present invention provides a flash memory and the manufacturing method thereof. Compared to conventional NAND flash memory, the flash memory set forth in the present invention includes common source lines, landing pads and bit line contacts so that each storage transistor can be operated individually and the operation speed can therefore be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory, comprising:
a substrate;
a memory string disposed on the substrate, wherein the memory string extends along a first direction and comprises a plurality of storage transistors;
a plurality of landing pads disposed between each of the storage transistors;
a plurality of common source lines and a plurality of bit line contacts arranged alternatively to electrically connect the landing pads, wherein the common source lines extends along a second direction which is substantially perpendicular to the first direction; and
at least a bit line disposed on the bit line contacts, wherein the bit line extends along the first direction and electrically connects the bit line contact.

2. The flash memory according to claim 1, further comprising a first dielectric layer disposed on the substrate, and a second dielectric layer disposed on the first dielectric layer.

3. The flash memory according to claim 2, wherein the storage transistors are disposed in the first dielectric layer.

4. The flash memory according to claim 2, wherein the landing pads are disposed in the first dielectric layer.

5. The flash memory according to claim 2, wherein the common source lines are disposed in the second dielectric layer.

6. The flash memory according to claim 2, wherein the bit line contacts are disposed in the second dielectric layer.

7. The flash memory according to claim 2, wherein the bit lines are disposed above the second dielectric layer.

8. The flash memory according to claim 1, wherein the landing pads comprise metal or poly-silicon.

9. The flash memory according to claim 1, wherein the common source lines comprise metal or poly-silicon.

10. The flash memory according to claim 1, wherein the bit lines comprise metal or poly-silicon.

11. A method of manufacturing a flash memory, comprising:
providing a substrate and forming an active region in the substrate;
forming a memory string in the active region, wherein the memory string comprises a plurality of storage transistors;
forming a first dielectric layer covering the memory string;
forming a plurality of landing pads in the first dielectric layer, wherein each landing pad is located between each of the storage transistors;
forming a plurality of common source lines on the first dielectric layer and forming a second dielectric layer covering the common source lines; and
forming a plurality of bit line contacts in the second dielectric layer, and a plurality of bit lines above the second dielectric layer to electrically connect the bit line contacts.

12. The method of manufacturing a flash memory according to claim 11, wherein the common source lines and the bit line contacts are arranged alternatively to electrically connect to the landing pads.

13. The method of manufacturing a flash memory according to claim 11, wherein the memory string extends along a first direction.

14. The method of manufacturing a flash memory according to claim 13, wherein the bit lines extend along the first direction.

15. The method of manufacturing a flash memory according to claim 13, wherein the common source lines extend along a second direction which is substantially perpendicular to the first direction.

16. The method of manufacturing a flash memory according to claim 11, wherein the landing pads comprise metal or poly-silicon.

17. The method of manufacturing a flash memory according to claim 11, wherein the common source lines comprise metal or poly-silicon.

18. The method of manufacturing a flash memory according to claim 11, wherein the bit lines comprise metal or poly-silicon.
